(19) United States
(12) Patent Application Publication
(10) Pub. No.: US 2008/0007917 A1
(43) Pub. Date: Jan. 10, 2008

(54) HEAT DISSIPATOR ASSEMBLY

(76) Inventor: Wei-Chun KAO, Chung-Ho City (TW)

Correspondence Address: HDSL, 4331 STEVENS BATTLE LANE, FAIRFAX, VA, 22033, US

(21) Appl. No.: 11/754,554

(22) Filed: May 29, 2007

(30) Foreign Application Priority Data
Jul. 6, 2006 (TW) 095211867

(51) Int. Cl. H05K 7/20

(52) U.S. Cl. 361/707

(57) ABSTRACT

A heat dissipator assembly for abutting against a heat-generating element includes a heat dissipator and a heat conductor. The heat dissipator has a base. The top of the base is provided with a plurality of heat-dissipating pieces, and the bottom of the base has an accommodating trough. The heat conductor is accommodated in the accommodating trough of the base. The periphery of the heat conductor is provided with a plurality of exhaust channels. Via the above arrangement, when the heat-conducting base is connected with the accommodating trough of the base, the air originally existing in the accommodating trough is pressed by the heat conductor and then is exhausted through the exhaust channels provided on the periphery of the heat conductor. In this way, the heat conductor can be connected with the accommodating trough of the base tightly, thereby enhancing the heat-conducting effect thereof.

### BACKGROUND OF THE INVENTION

1. Field of the Invention

The present invention relates to a heat-dissipating device, and in particular to a heat-dissipating structure that can be adhered on a heat-generating element directly.

2. Description of Prior Art

With the precision of technologies, electronic devices generate more and more amount of heat. In order to make the electronic device to operate successfully under a normal working temperature, a proper heat-dissipating effect plays an important role.

In order to increase the heat-dissipating performance of the electronic device efficiently, the most common way is to arrange a heat dissipator having a plurality of heat-dissipating pieces on a heat-generating element directly. As shown in FIG. 1, such kind of heat-dissipating structure includes a heat dissipator 1a and a heat-conducting pillar 2a. The heat dissipator 1a has a base 12a. The top of the base 12a has a plurality of heat-dissipating pieces 14a. Further, the bottom of the base 12a has an accommodating space 122a. The heat-conducting pillar 2a is adhered to the heat-generating element 3a and is accommodated in the accommodating space 122a of the base 12a. The area of the cross section of the heat-conducting pillar 2a is substantially the same as that of the accommodating space 122a, so that the periphery of the heat-conducting pillar 2a is connected tightly with the periphery of the accommodating space 122a. Via the high heat conductivity of the heat-conducting pillar 2a, the heat generated by the heat-generating element 3a can be conducted upwardly to the heat dissipator 1a and then to the outside through the plurality of heat-dissipating pieces 14a, thereby achieving the heat-dissipating effect.

However, the above design of the heat dissipator 1a has a drawback. Since the heat dissipator 1a is connected tightly with the heat-conducting pillar 2a, the diameter of the heat-conducting pillar 2a is designed to be slightly larger than or identical to that of the accommodating space 122a, so that the side edge of the heat-conducting pillar 2a abuts against the accommodating space 122a tightly and is fixed thereto after the heat-conducting pillar 2a is disposed in the accommodating space 122a. However, owing to such a tight connection, the air existing in the accommodating space 122a cannot be exhausted when the heat-conducting pillar 2a is connected with the accommodating space 122a. As a result, the top of the heat-conducting pillar 2a cannot be adhered completely to the top edge of the accommodating space 122a and thus a gap 4a is generated, which reduces the heat-conducting and heat-dissipating effects thereof directly. Therefore, it is necessary to improve the above structure.

### SUMMARY OF THE INVENTION

In view of the above drawbacks, the present invention is to provide a heat dissipator assembly. By providing a plurality of exhaust channels on the periphery of a heat conductor connected with the heat dissipator, the air stayed between the bottom of the heat dissipator and the heat conductor can be exhausted through the exhaust channels when the heat conductor is inserted into the bottom of the heat dissipator. In this way, the heat conductor can be connected tightly with the heat dissipator, thereby enhancing the heat-conducting and heat-dissipating effects.

In order to achieve the above objects, the present invention provides a heat dissipator assembly including a heat dissipator and a heat conductor. The heat dissipator has a base. The top of the base is provided with a plurality of heat-dissipating pieces, and the bottom of the base has an accommodating trough. The heat conductor is accommodated in the accommodating trough of the base. The periphery of the heat conductor is provided with a plurality of exhaust channels. Via the above arrangement, when the heat-conducting base is connected with the accommodating trough of the base, the air originally existing in the accommodating trough is pressed by the heat conductor and then is exhausted through the exhaust channels provided on the periphery of the heat conductor, thereby connecting the heat conductor with the top of the accommodating trough of the base tightly.

### BRIEF DESCRIPTION OF THE DRAWINGS

FIG. 1 is a cross-sectional view of a prior art;

FIG. 2 is an exploded perspective view of the present invention;

FIG. 3 is a cross-sectional view (I) showing the assembly of the present invention;

FIG. 4 is a cross-sectional view (II) showing the assembly of the present invention; and

FIG. 5 is an exploded perspective view showing another embodiment of the present invention.

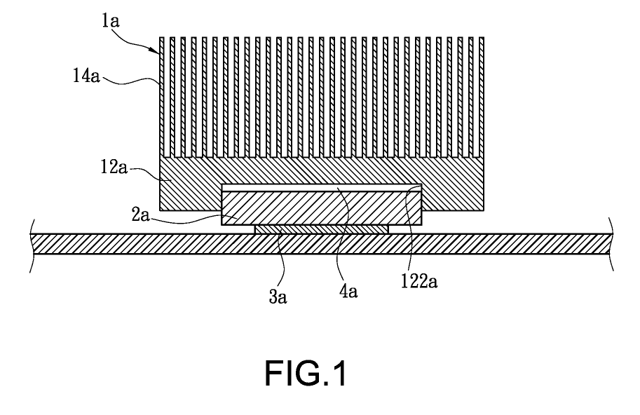

### DETAILED DESCRIPTION OF THE INVENTION

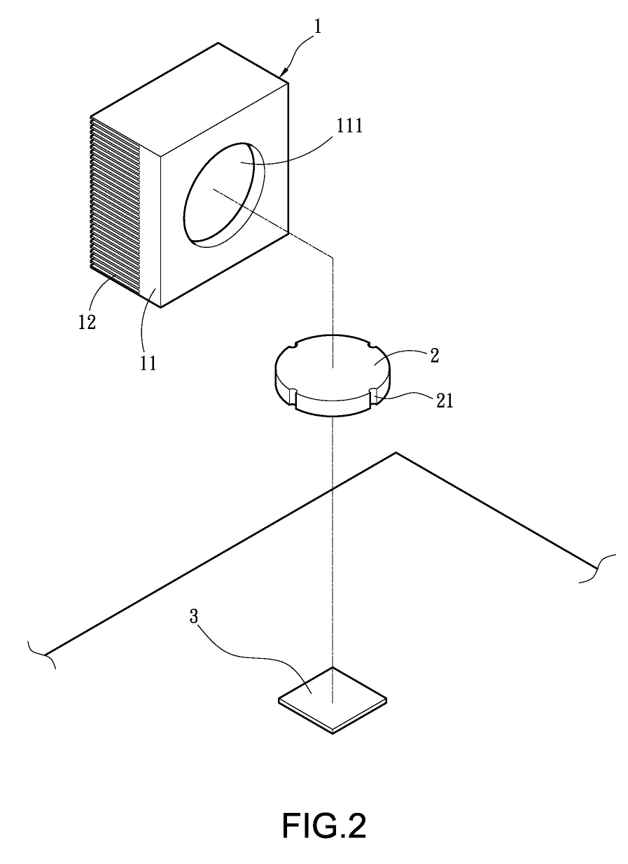

With reference to FIG. 2, it is an exploded perspective view of the present invention. The present invention includes a heat dissipator 1 and a heat conductor 2. The heat dissipator 1 has a base 11. The top of the base 11 is provided with a plurality parallel heat-dissipating pieces 12 that are integrally formed with the base 11. Further, the bottom of the base 11 is provided with an accommodating trough 111. In the present embodiment, the cross section of the accommodating trough 111 is formed into a circular shape. The heat conductor 2 is adhered to a heat-generating element 3. In the present embodiment, the heat conductor 2 is formed into a cylinder that is made of a material having high heat conductivity (such as copper). The heat conductor 2 is accommodated in the accommodating trough 111 of the base 11. Further, the cross section of the heat conductor 2 corresponds to that of the accommodating trough 111. Also, the area enclosed by the periphery of the heat conductor 2 is substantially identical to area of the accommodating trough 111, so that the side edge of the heat conductor 2 can be connected with the side edge of the accommodating trough 111 tightly. Further, the periphery of the heat conductor 2 is provided with at least one exhaust channel (four in this figure). The exhaust channel 21 is formed into a trough and penetrates through the upper and lower faces of the heat conductor 2.

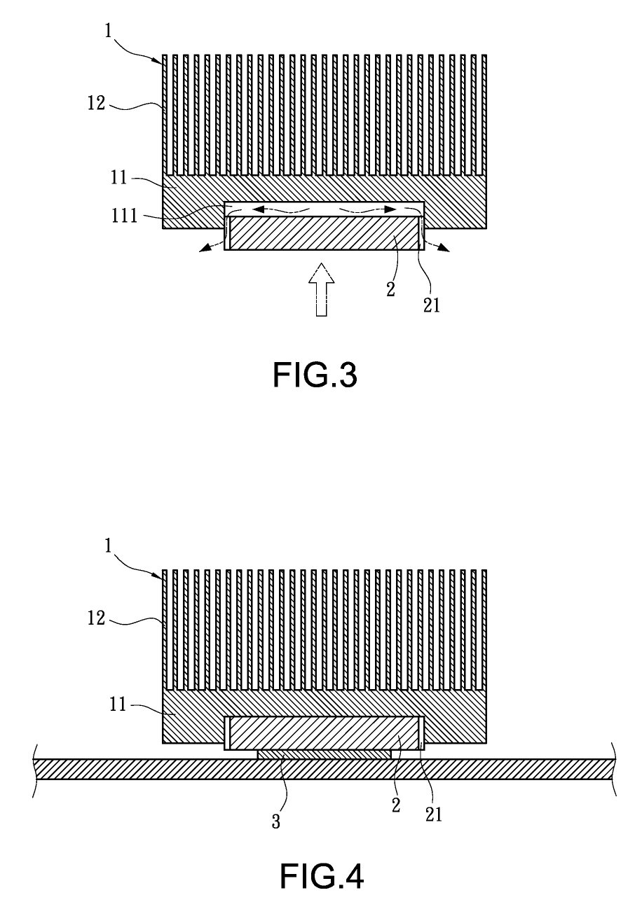

With reference to FIG. 3, it is a cross-sectional view showing the assembly of the present invention. It can be seen from this figure that when the hat conductor 2 is disposed in the accommodating trough 111 of the base 11, an external force may press the heat conductor 2 into the accommodating trough 111. At the same time, the heat conductor 2 presses upwardly the air remaining in the accommodating trough 111, so that the air will be exhausted to the outside through the exhaust channels 21 provided on the periphery of the heat conductor 2 (the direction indicated by the arrows is the direction of airflow). In this way, the top and the side edge of the heat conductor 2 can abut against the accommodating trough 111 of the base 11 tightly, as shown in FIG. 4. Therefore, via the heat-conducting effect of the heat conductor 2, the heat generated by the adhered heat-generating element 3 can be conducted to the heat dissipator 1 rapidly. Then, the plurality of heat-dissipating pieces 12 on the heat dissipator 1 perform a heat-dissipating action to keep the heat-generating element 3 to operate in a normal working temperature, thereby achieving an optimal heat-dissipating efficiency of the heat dissipator 1.

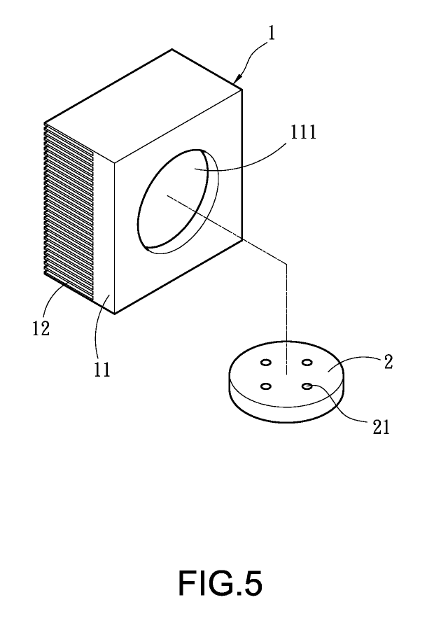

With reference to FIG. 5, it shows another embodiment of the present invention. It can be seen that the exhaust channels 21 can be arranged at any places of the heat conductor 2. As shown in this figure, the exhaust channels 21 are provided in the positions close to a center of the heat conductor 2 (four in this figure). Each of the exhaust channels 21 is formed into a penetrating hole that penetrates through the upper and lower faces of the heat conductor 2, thereby also achieving the effect of exhausting the air in the accommodating trough 111.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A heat dissipator assembly, comprising:
a heat dissipator having a base thereon, a bottom of the base having an accommodating trough; and
a heat conductor adhered to a heat-generating element and connected in the accommodating trough of the base tightly, the heat conductor being provided with at least one exhaust channel.

2. The heat dissipator assembly according to claim 1, wherein the exhaust channel is provided on a periphery of the heat conductor.

3. The heat dissipator assembly according to claim 2, wherein the exhaust channel is a trough.

4. The heat dissipator assembly according to claim 1, wherein the exhaust channel is provided in a position close to a center of the heat conductor.

5. The heat dissipator assembly according to claim 4, wherein the exhaust channel is a penetrating hole.

6. The heat dissipator assembly according to claim 1, wherein the heat conductor is a cylinder.
